(19) United States
(12) Patent Application Publication
(10) Pub. No.: US 2017/0322247 A1
(43) Pub. Date: Nov. 9, 2017

(54) DEVICE AND METHOD FOR RF EXPOSURE ASSESSMENT AT MILLIMETER WAVE FREQUENCIES

(71) Applicant: QUALCOMM Incorporated, San Diego, CA (US)

(72) Inventors: Lin LU, San Diego, CA (US); Jagadish NADAKUDUTI, La Jolla, CA (US); Paul GUCKIAN, San Diego, CA (US)

(21) Appl. No.: 15/348,745

(22) Filed: Nov. 10, 2016

Related U.S. Application Data
(60) Provisional application No. 62/332,400, filed on May 5, 2016.

(51) Int. Cl. G01R 29/08

(52) U.S. Cl. CPC G01R 29/0857; G01R 29/0878

(57) ABSTRACT

A device and method for determining power density measurements of electromagnetic (EM) transmissions from an antenna of a wireless electronic device are disclosed. The method can include determining one or more worst case configurations within an exposure plane based on a power density distribution of the antenna in free space. The method can also include measuring power density distribution across a first plane at a first distance from the exposure plane and across a second plane at a second distance from the exposure plane. The method can also include first back transforming power density distribution of the first plane to the second plane, second back transforming power density distribution from the first plane to the exposure plane, and third back transforming power density distribution from the second plane to the exposure plane, for the one or more worst case configurations.

### CROSS REFERENCE TO RELATED APPLICATIONS

The application claims the benefit of priority to U.S. Provisional Patent Application 62/332,400, filed May 5, 2016, entitled “DEVICE AND METHOD FOR RF EXPOSURE ASSESSMENT AT MILLIMETER WAVE FREQUENCIES,” the contents of which are hereby incorporated by reference in its entirety.

### BACKGROUND

### Technological Field

This disclosure relates to electromagnetic energy exposure. More specifically this disclosure relates to systems and methods for measuring and assessing radio frequency (“RF”) exposure levels from devices using millimeter wave (mmWave) components.

### Related Art

Electromagnetic (EM) and radiofrequency (RF) transmissions can be measured in a number of ways. Power density may be referred to herein in terms of RF energy, Watts per square meter (W/m²), at a given location. Specific absorption rate (SAR) is a measure of the rate at which energy is absorbed by the human body when exposed to a radio frequency (RF) electromagnetic field; although, it can also refer to absorption of other forms of energy by tissue, including ultrasound. It is defined as the power absorbed per mass of tissue and has units of watts per kilogram (W/kg).

SAR measures exposure to electromagnetic fields between 100 kHz and 10 GHz. SAR can be used to measure power absorbed by the human body, for example, from mobile phones and during MRI scans. The value power density and SAR can depend heavily on the geometry of the part of the body and tissue structure that is exposed to the RF energy, and on the relative location, geometry, operating frequency, and radiating power of the RF source. Thus various tests can be performed using each specific source at the intended position of use.

### SUMMARY

One aspect of the disclosure provides a method for determining power density measurements of electromagnetic (EM) transmissions from an antenna of a wireless electronic device, the antenna having an aperture plane. The method can include measuring, with a measuring device having a measurement error, a first power density distribution of the transmissions across a scan plane, the scan plane being parallel to and separated from the aperture plane and by a first distance. The method can also include determining, by a controller, a first back transformed power density distribution of the transmissions across a transform plane using the first power density distribution, the transform plane being parallel to and separated from the aperture plane by a second distance, the second distance being different than the first distance. The method can also include measuring, with the measuring device, a second power density distribution of the transmissions across an inclined scan plane, the inclined scan plane being non-parallel to aperture plane, the inclined scan plane and the scan plane intersecting at a first intersection. The method can also include determining, by the controller, a second transformed power density distribution of the transmissions across an inclined transform plane using the second power density distribution, the inclined transform plane being parallel to the inclined scan plane and intersecting the first transform plane at a second intersection. The method can also include determining, by the controller, that the second back transformed power density distribution is within a measurement error of the first back transformed power density distribution at the second intersection.

Another aspect of the disclosure provides a method for determining power density distribution of electromagnetic (EM) transmissions across an exposure plane of an antenna of a wireless electronic device, the exposure plane being nonparallel to an aperture of the antenna. The method can include determining, by a controller, one or more worst case configurations within an exposure plane based on a power density distribution of the antenna in free space. The method can also include measuring, with a measuring device having a measurement error, power density distribution in amplitude and phase in two polarizations across a first plane at a first distance from the exposure plane and across a second plane at a second distance from the exposure plane, the first plane and the second plane being parallel to the exposure plane. The method can also include first back transforming, by the controller, power density distribution of the first plane to the second plane for the one or more worst case configurations. The method can also include second back transforming, by the controller, power density distribution from the first plane to the exposure plane for the one or more worst case configurations. The method can also include third back transforming, by the controller, power density distribution from the second plane to the exposure plane for the one or more worst case configurations.

Another aspect of the disclosure provides a device for determining power density distribution of electromagnetic (EM) transmissions across an exposure plane of an antenna of a wireless electronic device, the exposure plane being nonparallel to an aperture plane of the antenna. The device can have a measuring device operable to measure power density distribution of the antenna in amplitude and phase in two polarizations across a first plane at a first distance from the exposure plane and across a second plane at a second distance from the exposure plane, the first plane and the second plane being parallel to the exposure plane. The device can also have a controller. The controller can determine one or more worst case configurations within the exposure plane of the antenna based on a power density distribution of the antenna in free space. The controller can also first back transform power density distribution of the first plane to the second plane for the one or more worst case configurations. The controller can also second back transform power density distribution from the first plane to the exposure plane for the one or more worst case configurations. The controller can also third back transform, power density distribution from the second plane to the exposure plane for the one or more worst case configurations.

Another aspect of the disclosure provides a non-transitory computer-readable medium for determining power density distribution of electromagnetic (EM) transmissions across an exposure plane of an antenna of a wireless electronic device, the exposure plane being nonparallel to an aperture plane of the antenna. The medium can have instructions that when executed by one or more processors cause a computer to determine one or more worst case configurations within an exposure plane based on a power density distribution of the antenna in free space. The instructions can also cause the computer to measure power density distribution in amplitude and phase in two polarizations across a first plane at a first distance from the exposure plane and across a second plane at a second distance from the exposure plane, the first plane and the second plane being parallel to the exposure plane. The instructions can also cause the computer to back transform power density distribution of the first plane to the second plane for the one or more worst case configurations. The instructions can also cause the computer to back transform power density distribution from the first plane to the exposure plane for the one or more worst case configurations. The instructions can also cause the computer to back transform power density distribution from the second plane to the exposure plane for the one or more worst case configurations.

### BRIEF DESCRIPTION OF THE DRAWINGS

The details of embodiments of the present disclosure, both as to their structure and operation, may be gleaned in part by study of the accompanying drawings, in which like reference numerals refer to like parts, and in which:

FIG. 1 is a schematic representation of an antenna and probes;

FIG. 2 is a sectional view of an embodiment of a mobile electronic device having the antenna of FIG. 1;

FIG. 3 is a graphical representation of method for power density measurement of the antenna of FIG. 1;

FIG. 4 is a flowchart of a method for determining power density distribution at an exposure plane in multiple transmission configurations;

FIG. 5 is a flowchart of another method for determining power density distribution at an exposure plane in multiple transmission configurations.

FIG. 6 is a functional block diagram of a device for implementing the methods disclosed herein.

### DETAILED DESCRIPTION

RF transmissions can be described in terms of power density of a wireless electronic device (W/m²) and SAR, or the measure of the rate of absorption by the body of RF energy from the wireless electronic device. In some cases the source of the RF energy can be a wireless electronic device, such as, for example, a cell phone, a laptop computer, or other device with wireless communication capabilities. SAR and power density measurements can provide a straightforward means for measuring the RF exposure characteristics of wireless electronic devices to ensure that the antenna transmissions are within set predetermined limits. Such predetermined limits can be certain safety guidelines, governing rules, or regulations, such as, for example, those set by the U.S. Federal Communications Commission (FCC).

Wireless mobile devices can implement various wireless transmission protocols. Some of these protocols can be one or more of the various cellular or Wi-Fi standards, such as, for example, the family of IEEE 802.11 standards. In some embodiments described herein, the 802.11ad standard may be used as a primary example. However, the devices and methods described can be adapted for use with other wireless transmission protocols or systems without departing from the spirit of the disclosure.

IEEE 802.11ad systems can use directional antennas that operate in the millimeter wave (mmWave) spectrum. In some examples, 802.11ad systems can operate as high as 60 gigahertz (GHz). The FCC certification of wireless devices operating at such mmWave applications requires evaluation of power density in the surrounding regions where human body is present. As used herein, mmWave refers generally to frequencies in excess of ten (10) gigahertz (GHz). This disclosure relates to simulations and measurements for various test procedures for mmWave-enabled wireless devices operating at these frequencies.

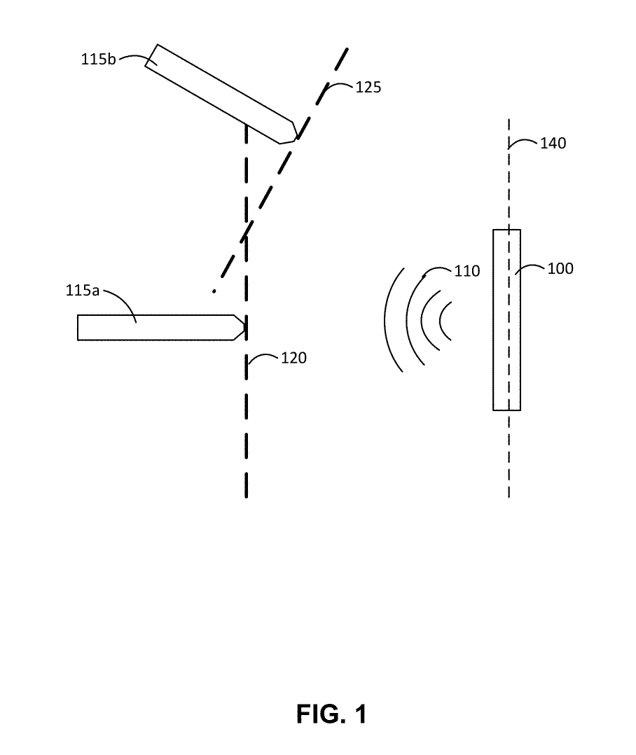

FIG. 1 is a schematic representation of an antenna transmission. An antenna module (antenna) 100 can transmit EM radiation 110 toward a scan plane 120 (shown as a dashed line). In some embodiments, the antenna 100 can transmit according to the IEEE 802.11ad standard. Accordingly, the antenna 100 can be a directional antenna having multiple antenna elements arranged in an array and capable of beamforming, for example. A measurement device, or a probe 115 can be used to measure the EM radiation 110 at the scan plane 120. It should be noted that the power measured by the probe 115 can be mathematically converted into values of power density or field strength. Both, power density and field strength are mathematically related and thus one can be converted into the other. Accordingly, these terms may be used interchangeably without deviating from the concepts explained herein.

The probe 115 is shown in two positions indicated using letters as probe 115a and probe 115b. The probe 115a is positioned at the scan plane 120. In some examples, the scan plane 120 can be oriented parallel to an aperture of the antenna 100. The aperture can describe the planar face of the antenna 100 and lie in or be parallel to an aperture plane 140. The aperture plane 140 is indicated by a vertical dashed line through the center of the antenna 100. The distance between the aperture plane 140 and the scan plane 120 can vary according to the frequency(ies) at which the antenna 100 is transmitting and what tests are being conducted. In some embodiments, the distance from the antenna 100 (and e.g., the aperture plane 140) to the probe 115a can be a multiple of the wavelength of the EM radiation 110.

The antenna 100 can transmit multiple beams. A main beam can be radiation (e.g., the EM radiation 110) transmitted from the antenna 100 in a direction orthogonal to the aperture plane 140, for example. Other beams or side lobes from of the EM radiation 110 may be present, but may not be specifically described herein.

In some examples, far-field power density measurements can be made toward the main beam of a transmitter (e.g., the antenna 100). Such a measurement can assess worst-case exposure in that direction using various simulations. This is illustrated by the use of the probe 115a in evaluating power density at the scan plane 120, where the scan plane 120 is parallel orientation relative to the aperture plane 140. However, if a human body is present in other directions other than in the main beam (e.g., the side lobes), assessed radiation exposure may be overly conservative, limiting the maximum allowable transmission power for the 802.11ad module (e.g., the antenna 100). For example, the scan plane 120 can be moved to an inclined angle that is not parallel to the aperture plane 140, such as an inclined scan plane 125. The power density of the EM radiation 110 measured by the probe 115b may then be less than at the probe 115a, given the attenuation of the EM radiation 110 at locations not directly in front of the antenna 100 or within the main beam. Accordingly, using a power density measurement at the scan plane 120 may be artificially high if applied to a location on the inclined scan plane 125. While the scan plane 120 and the inclined scan plane 125 are shown as a line in a single dimension, it should be appreciated that the scan plane 120 and the inclined scan plane 125 should be understood as two dimensional entities over which values of measured power density can vary, depending on location and aspect to the EM radiation 110.

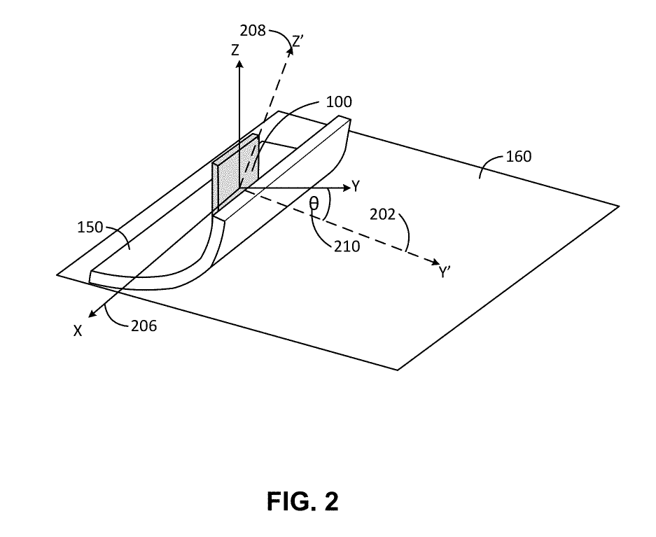

FIG. 2 is a perspective view of a portion of a mobile electronic device having the antenna of FIG. 1. The antenna 100 can be installed in a wireless electronic device (device) 150, for example. Only a portion of the device 150 is depicted in this view. The device 150 can be, for example, a laptop computer, a mobile phone, or other wireless or mobile electronic device. The antenna 100 can also be installed in nearly any portable electronic device for use in wireless communication. As shown, the device 150 can be a portion of a laptop computer with antenna 100 installed at the hinge inside a laptop (e.g., the device 150). In some examples the portion of the device 150 shown can be a portion of the lower back panel of a laptop computer where the base of the laptop meets the display, for instance. As shown, the antenna 100 is oriented parallel to the z-axis. Accordingly, the aperture plane 140 (FIG. 1) is parallel to the XZ plane and can transmit the main beam (e.g., the EM radiation 110) in the direction indicated by the y-axis. While the scan plane 120 (FIG. 1) is considered to be orthogonal to the y-axis (and parallel to the aperture plane 140), power density measurements made in the scan plane 120 may not accurately reflect the power density levels actually experienced in a plane that is not parallel (e.g., the inclined scan plane 125) to the aperture plane 140 or the scan plane 120.

In some embodiments, an exposure plane 160 can be used to measure, test, and evaluate power density of the antenna 100 at a position not directly in front of or parallel to the aperture plane 140. The exposure plane 160 can be similar to the inclined scan plane 125 (FIG. 1) and lie at an angle not perpendicular to the y-axis of FIG. 2 (and the main beam). An inclined vertical axis 208 can define a vertical axis, or Z′ axis, of the exposure plane 160 perpendicular to the X axis 206. The inclined vertical axis 208 is deflected from the vertical Z axis by an angle (θ) 210. An inclined horizontal axis 202 can further describe a horizontal axis (Y′ axis) of the exposure plane 160 perpendicular to the X axis 206. Thus, the exposure plane 160 is parallel to the XY′ plane and orthogonal to the XZ′ plane, as shown. The angle 210 describes the angular difference between the aperture plan 140 (e.g., shown in FIG. 2 as the XZ plane) and orthogonal to the exposure plane 160 (e.g., shown in FIG. 2 as the XZ′ plane).

The device 150 can be positioned, for example, in a user's lap, on top of the user's legs. In such an example, the user's legs can lie in or define the exposure plane 160. As used herein, the exposure plane 160 can contain or describe a position having the closest distance to the antenna 100 where the human body (e.g., the user) is exposed. This is done in order to identify worst-case antenna module-to-body (e.g., the antenna 100) transmission configurations.

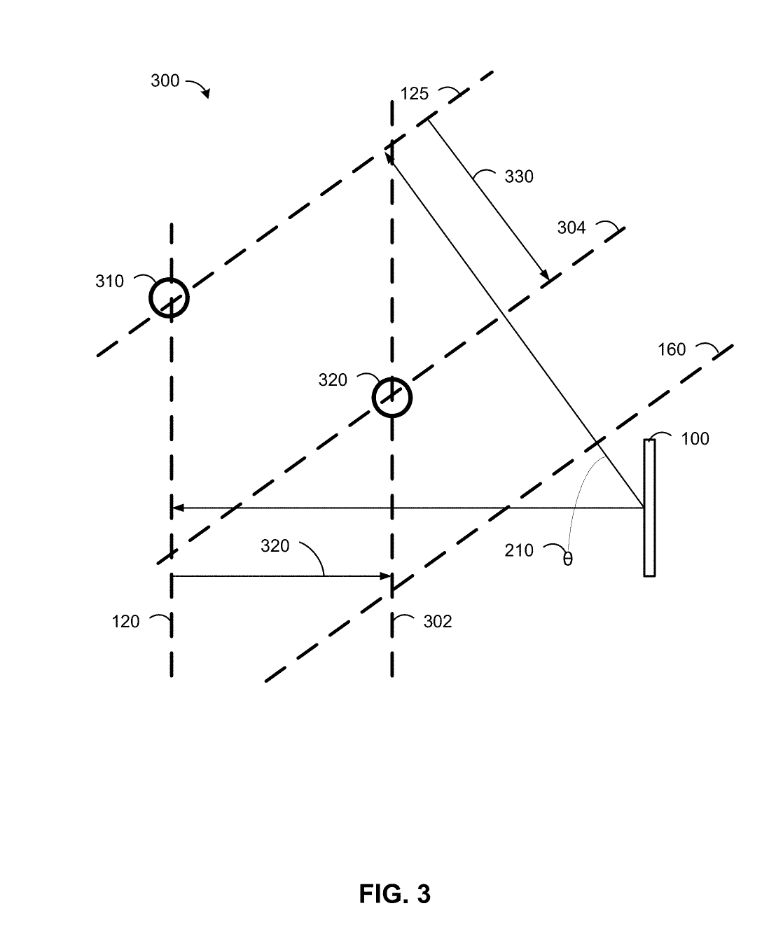

FIG. 3 is a graphical representation 300 of method for power density measurement of the antenna of FIG. 1. The method illustrated in FIG. 3 can be used to validate the accuracy of a power density measurement of the EM radiation 110 taken at an angle not orthogonal to the aperture plane 140, for example, in the inclined scan plane 125 (e.g., parallel to the exposure plane 160 in FIG. 3).

In some examples, the antenna 100 can be, for example, a two by four patch antenna installed in the back of a laptop (e.g., the device 150) as shown in FIG. 2. As used herein, “two by four” refers to the number of antenna elements in the antenna 100. In such an embodiment, there are two rows and four columns resulting in eight patch antenna elements. In some other examples, the number of elements as well as the type of elements can be different. Also, not all elements may be the same. For example, the antenna elements can be a combination of patch antenna elements, dipole antenna elements, or any other kind of antenna elements). In some other embodiments, the elements need not be arranged in a fixed spacing array. As disclosed herein the grid is set as 2×4 as a primary example, however the elements can be positioned in arbitrary locations on the 802.11ad module (e.g., the antenna 100). In some examples, other arrangements are possible. The antenna 100 can have the aperture plane 140 and transmit a main lobe of EM radiation 110 away from the antenna 100 toward the scan plane 120. It should be also noted that as the amplitude and phase of transmission signal fed to these antenna elements changes (i.e., varying the amplitude and phase of each element), the main beam can be steered along a direction away from scan plane 120. The power density of the EM radiation 110 can then be measured in the scan plane 120. In some examples, the measurements can be made at a multiple of the wavelength (λ) of the transmission of the antenna 100. The distance can be, for example, 20 mm from the antenna 100. At 60.5 GHz for example, the wavelength (λ) of the EM radiation 110 is approximately 5 mm. Thus the scan plane 120 shown in FIG. 3 can be expressed as being 4λ (5*4=20 mm) from the antenna 100. It should be appreciated that other distances that are not exact multiple of wavelength (e.g., 19 mm) can be used without departing from the disclosure.

In some embodiments, such measurements can be taken (by, e.g., the probe 115) within the near field of the antenna 100 in order to model the actual antenna transmission and power density. The measurements can then be input into a mathematical model to simulate and/or evaluate the transmission patterns of the antenna 100.

In some examples, the probe 115 is used at a distance in the near field of the antenna 100 (e.g., 4λ). If power density measurements are taken too close to the antenna 100, the probe 115 or other instrument can interfere with or distort the antenna beams (e.g., the EM radiation 110) and negatively affect the measurement. This can distort the resulting model of the antenna 100. Accordingly, power density measurements can be taken at a distance and then back transformed toward the aperture plane 140 in order to calculate a theoretical field strength (or power density) at a different distance from the antenna 100 based on the remote measurements.

As used herein the “back transform” or “back transformation” for near field EM radiation pattern simulation can be accomplished using the plane wave spectrum (PWS) method. The PWS method is described in references Wang, J. J. H, “An examination of the theory and practices of planar near-field measurement”, IEEE Transactions on Antennas and Propagation, 36(6): 746-753, June 1988; and Yaghjian, A. “An Overview of Near-Field Antenna Measurements”, IEEE Transactions on Antennas and Propagation, 34(1): 30-44, January 1986, both of which are hereby incorporated by reference in their entirety. For example, using the PWS method as in these references, planar scanning techniques in near-field measurement of antennas can be used to determine a relationship between the near-field samples. Then using the principles of the PWS method, a far-field pattern can be computed. As used herein, the opposite can also be achieved, that is, a near-field transmission pattern at the aperture plane of the antenna can be computed from near-field samples a few wavelengths from the aperture plane.

Near field measurements are typically performed at about one to 10 wavelengths from the antenna 100. Measurements taken too close to the antenna 100 will perturb the EM fields resulting in measurement errors, while measurements taken too far from the antenna 100 may result in an inability to measure weak areas of signal distribution due to attenuation. For example, measurements taken too far away may be below the noise floor or the sensitivity of the measurement system (e.g., the probe 115).

In some embodiments, measurements of the field strength or power density can be taken at multiple locations along the scan plane 120 or in the inclined scan plane 125. A plurality of measurements can be taken along the scan plane 120. For example, the measurements can span 114 measurements by 114 measurements (114×114) with 2 mm between each measurement. The remaining values between each measurement can be interpolated to provide continuous values across the scan plane 120. Thus the measurements can span an area 9 inches (“in.”) by 9 in. lying within the scan plane 120 and extending out of the page. Such measurements can be taken within the near field of the antenna 100 in order to model the actual antenna transmission and power density at, for example, the aperture plane. The measurements can then be input into a mathematical model to simulate and/or evaluate the transmission patterns of the antenna 100. It should be appreciated that other dimensions apart from 114×114 can be used without departing from the disclosure.

As shown in FIG. 3, the scan plane 120 can be back transformed 320 by 10 mm (e.g., 2λ), or one-half of the distance from the antenna 100, to a transform plane 302. In some embodiments, other measurements can be used to evaluate the simulation. The PWS method can provide a field strength or power density estimation at a location on the transform plane 302, or another desired location. This can aid in the simulation of the radiation 110 pattern from the antenna 100.

Additional field strength measurements can be taken along the inclined scan plane 125 (e.g., with another 114×114 measurements, similar to above). The inclined scan plane 125 is shown having an offset of approximately 65 degrees from the scan plane 120. The PWS method can also be used to back transform 330 the field strength one-half of the distance from the inclined scan plane 125 at an inclined transform plane 304. The inclined scan plane 125 is shown at a distance of 22.72 mm from the center of the antenna 100. Thus, similar to above, the inclined transform plane 304 is back transformed one-half of the distance from the antenna 100 by 11.36 mm. In such an embodiment, 20 mm-to-10 mm and 22.72 mm-to-11.36 mm are merely examples of various spacing. It should be appreciated that any distance can be used for measurement and back transformation. The distance of 22.72 mm was selected as an arbitrary distance for the inclined scan plane 125 to evaluate the method. Additionally, the back transformed distances of 10 mm for scan plane 120 and 11.36 mm for the inclined scan plane 125 (half the separation distance) are also arbitrary to evaluate this method.

As shown, the scan plane 120 intersects with the inclined scan plane 125 at a first intersection 310. The exemplary 114×114 power density measurements taken at the scan plane 120 (and associated interpolations) can provide a basis for comparison to the similar 114×114 measurements taken at the inclined scan plane 125. As part of a validation procedure, the values of the EM field strength or power density measurements at the first intersection 310 can be compared. The first intersection 310 can represent a line (oriented perpendicular to, or in and out of the page) that defines the intersection of the scan plane 120 and the inclined scan plane 125.

In a similar manner, the transform plane 302 intersects with the inclined transform plane 304 at a second intersection 320. Similarly, the second intersection 320 can represent a line (oriented perpendicular to, or in and out of the page) that defines the intersection of the transform plane 302 and the inclined transform plane 304. Thus, the PWS method calculations of the field strength of the EM radiation 110 at the second intersection 320 can be compared. The calculations and hence the field simulation using the PWS method can then be validated if the respective values of field strength (in the scan plane 120 and inclined scan plane 125) at the first intersection 310 and (in the transform plane 302 and inclined transform plane 304) at the second intersection 320 are within the measurement uncertainty of the probe 115 used to measure the EM radiation 110. Accordingly, measurement of power density along the inclined scan plane 125 can be used as a valid area in which to measure and evaluate the emissions from the antenna 100. This can aid in determining whether the emissions are within predetermined limits. The predetermined limits can be a function of certain federal regulations or other rules governing EM radiation. Accordingly, such a method can aid in evaluation of compliance with certain relevant regulations such as, for example, FCC regulations. This method and validation can then be extended to the use with the exposure plane 160 (i.e., parallel to inclined scan plane 125). Therefore, the accuracy and utility of power density measurements are not limited to those taken exclusively at the scan plane 120.

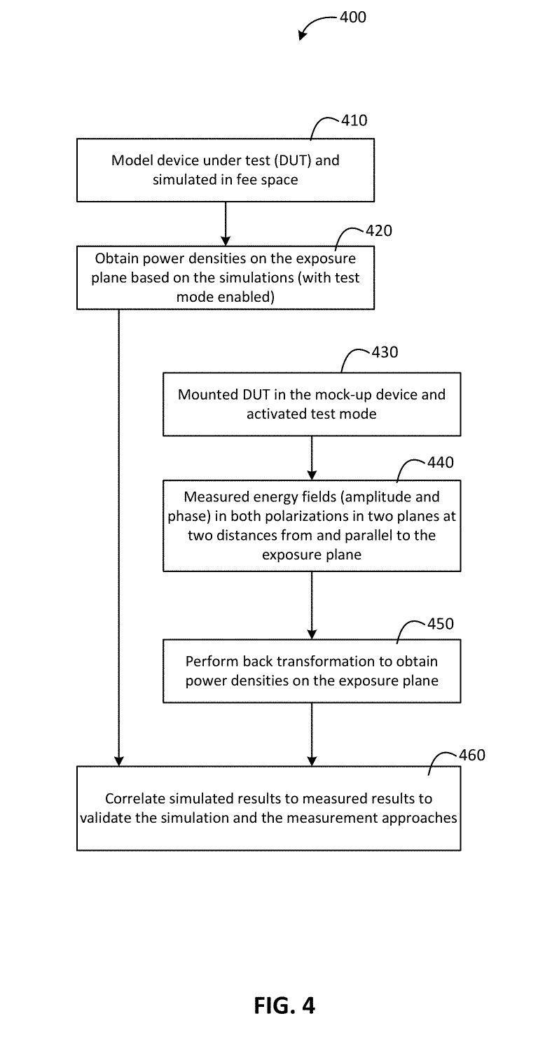

FIG. 4 is a flowchart of a method for determining power density distribution at an exposure plane in multiple transmission configurations. A method 400 can use the principles described above in connection with FIG. 2 and FIG. 3 to compare and validate the simulations of the power density distribution of the antenna 100 at various distances and in one or more locations. The method 400 can be used to derive reliable power density measurements across planes not parallel to the aperture plane 120. In some embodiments, simulation and measurement approaches for a known source (e.g., the antenna 100) and for an antenna module in test mode can be correlated to determine such power density distribution.

At block 410, the antenna 100 or device under test (DUT) can be modeled (e.g., computer-modeled) and/or simulated in free space. Since the DUT containing several antenna elements can be excited with different amplitudes and phases to steer the main beam, computer simulations can determine “worst case” configurations. As used herein, worst case configurations may refer to combinations of amplitudes and phases of antenna elements that result in the highest power density in the exposure plane 160. Accordingly, the simulations can reduce the number of measurements to only a few worst case configurations, instead of measuring all possible amplitude and phase combinations of antenna elements (e.g., the antenna 100) supported by the wireless device 150. This can reduce time and expense. As simulations model the antenna 100 without reference to the structure of the entire wireless device 150, the simulations can provide relative measure of exposure and be used to determine the worst amplitude/phase combinations. The worst case configurations can then be measured to demonstrate compliance with a given standard.

In some embodiments, only the antenna 100 is simulated in free space due to the lack of information regarding the specific material properties of the device 150 housing and other surroundings at mmWave frequencies. In such an example, the actual housing and other structures surrounding (e.g., plastics or metal housings) the antenna 100 (e.g., in a completed laptop or the device 150) may not be transparent to mmWave transmissions. Using the complete device 150 for such a test can produce different power density distributions. Since the wireless device can transmit in various configurations (e.g., combinations of amplitudes and phases used to excite different antenna elements of antenna array), the free space simulation can provide a relative standard or a relative control to determine, for example, a few of the top configurations (e.g., the top 3 to 5) that produce the highest exposure (power density). Then, measurements can be performed for these pre-selected few high or worst case configurations that are likely to generate highest power density. Using these worst case test configurations can determine if the wireless device 150 is compliant with regulatory limits for all these measured configurations.

In some embodiments the simulations can be used to assess and/or simulate near field power density of the antenna 100. At block 410, the antenna 100 can be simulated in free space to determine the high power density transmission configurations, or other exposure metrics in the exposure plane 160. This can reduce the number of test configurations required to demonstrate compliance as only the few high power density test configurations are measured. Additionally, this step can also validate the measurement setup in terms of accuracy of measured or calculated power density distributions in the exposure plane 160 by comparing the measured results to simulation results for one test configuration.

At block 420, power densities on the exposure plane 160 can be obtained from the model or simulation. In some examples, the antenna 100 can have a test mode that is measured or simulated for this portion of the process. The test mode can limit the number of antenna elements that transmit at a given time. In some examples, one or more signals with various amplitude and phase combinations can be transmitted by the antenna array elements, resulting in steered or directional antenna beam. A simple “test mode,” can be, for example, for transmitting from only one antenna element of all of the antenna array elements. This can provide a base line measurement for a single antenna element.

At block 430, the DUT (e.g., the antenna 100) can be mounted in a mock-up of the device 150, for example. In some examples, a mock-up of the device 150 can be formed of a material that is transparent to the mmWave radiation (e.g., the EM radiation 110) to eliminate variables in the test. This can more closely simulate free space as in the computer model of block 410. The mock-up of the device 150 can provide a way, for example, to orient the antenna 100 in a specific angle (e.g., the angle 210) with respect to the exposure plane 160 that closely simulates the actual angle of the antenna inside the complete device relative to the exposure plane 160.

At block 440, the power density of the EM radiation 110 can be measured across two different planes, a first plane at a first distance and a second plane at a second distance. In general, the first distance can be a multiple of the second distance, and for example, inclined to the aperture plane 140. For example, the antenna transmissions (e.g., the EM radiation 110) can be measured at the 4λ plane (e.g., the scan plane 125 that is 4λ away from the exposure plane 160 in FIG. 3) and the 2λ plane (e.g., the transform plane 304 that is a away from the exposure plane 160 in FIG. 3) in both amplitude and phase and in both polarizations.

At block 450, back transforms using the PWS method can be performed to obtain the power densities, or power density distribution, across the exposure plane 160 (e.g., 4λ towards the antenna from the inclined scan plane 125).

At block 460, the simulated results from block 420 can be compared with the back transformations at block 450 determined from measurements at block 440. Accordingly, block 460 involves comparing two independent approaches: 1) measurements taken in the inclined scan plane 125 that are back transformed to the exposure plane 160; and 2) computer simulations conducted to directly obtain power density distributions at the exposure plane 160 without relying on physical measurements. As noted above, the probe 115 has some measurement uncertainty. Similarly, the computer simulation can also have some simulation error or tolerance.

In some embodiments, the method 400 is validated at block 460 if the simulated results from block 420 are within a measurement uncertainty and/or simulation error of the measured results of block 450. The measurement uncertainty can be a tolerance or margin of error exhibited by the measurement device (e.g., the probe 115). Measurement uncertainty can also include uncertainties from measuring equipment (e.g., the probe 115 or other signal analyzer, signal meter), from perturbations caused by proximity of the probe 115 to the antenna 100, probe positioning, or uncertainty in source (e.g., variation in transmission signal strength fed to the array elements of the antenna 100).

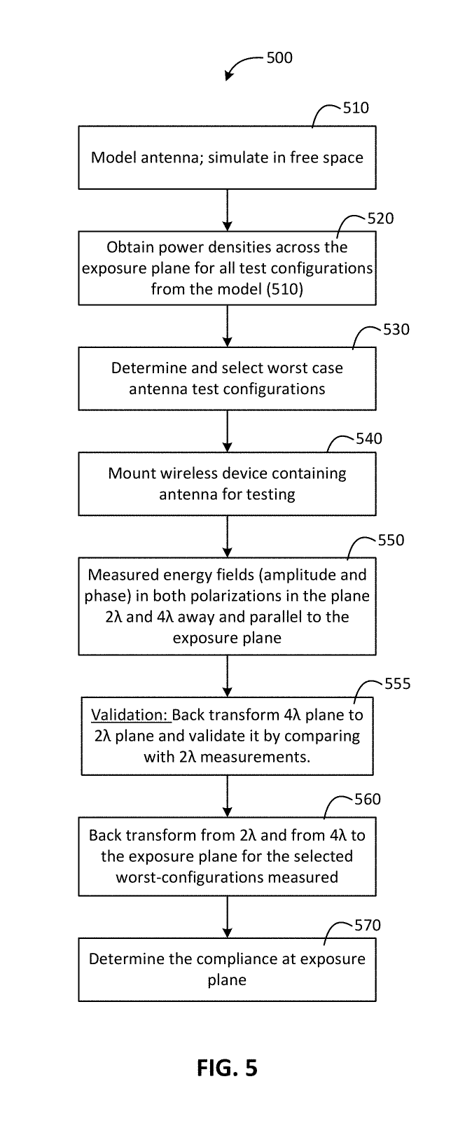

Such comparisons can validate the PWS calculation and the accuracy of the measurements. Correlated values can allow replacement of the mock-up of device used in block 430 with the actual device (see, block 540 in FIG. 5) using the same PWS calculations on the new measurements to estimate power density in the exposure plane 160. Again this can demonstrate compliance with a given standard. If the values correlate, the comparison validates both measurement and simulation approaches.

The accuracy of the EM field distribution (e.g., the EM radiation 110) resulting from the PWS back transformation relies on accurate relative amplitude and phase measurement at the scan plane 125. Similarly, determination of the power density distribution in exposure plane 160 can vary with the accuracy of the absolute amplitude measurement in scan plane 125. In order to validate the test setup that is accurate for absolute amplitude measurement and phase measurement, at block 460 the measurement result(s) are compared with the simulated result(s) in the exposure plane 160. Since the measurement and simulation are two independent approaches, the two methods can validate each other. In some examples, the method 400 can be a validation step prior to measuring actual device in method 500.

FIG. 5 is a flowchart of another method for determining power density distribution at an exposure plane in multiple transmission configurations. A method 500 can be used to determine power density distribution across the exposure plane 160. In some examples, the method 400 can be performed prior to performing the method 500 using the mock-up of device 150 and the antenna 100 for validating the accuracy of measurements and PWS calculations. The goal of the simulation is to perform the relative comparison and determine the worst-case antenna test configurations of the antenna 100 having the highest power density value, and then perform the measurement on the identified worst cases. As used herein, measurements on the worst case configurations indicate the intensity of the highest power density averaged over 1 cm² area within the exposure plane 160 out of all test configurations. The method 500 can aid in determining the highest power density in the exposure plane 160 out of all the test configurations. If such a value is less than a regulatory limit, for example, then the wireless device 150 is compliant. The simulation results in 520 show that power density in the exposure plane 160 for the remaining test configurations is lower than these identified worst cases. Therefore, if the estimated power density in the exposure plane 160 is lower than regulatory limits for all the measured worst-case configurations then it implies that all the remaining test configurations are also lower than regulatory limits. This can be done, for example, to demonstrate the compliance with various regulations. In some embodiments, the top three worst-case configurations can be evaluated. The method 500 can be used to compare power density levels or distribution of those levels among antenna test configurations of the antenna 100 so as to determine the three worst-case sectors having, for example, the highest peak 1 cm²-averaged power density in the exposure plane 160. Near-field power density in free-space in 520 can be estimated by extracting the Poynting vector at the bottom surface (exposure plane 160) of the device 150 at a frequency of 60.5 GHz for each sector of the EM radiation 110 for comparison.

Amplitude and phase of the energy fields (e.g., the EM radiation 110) can be measured for the worst-case sectors at, for example, 10 mm (−2λ), from the bottom surface (e.g., the exposure plane 160) of the device 150. Using the PWS method, the measured fields can be back transformed to the exposure plane 160 and then spatially averaged over 1 cm² or any other spatial area specified by the regulatory bodies. This can provide power density distribution in the exposure plane 160. Then, a 1 cm²-spatial averaging over this distribution can be performed to determine 1 cm²-averaged power density distribution. Peak value in this 1 cm²-averaged power density distribution should be less than the regulatory limit.

In general, the methods disclosed herein can include near-field measurements at a plane that is a multiple of the wavelength (e.g., 4λ) away from the antenna 100 and parallel to the exposure plane 160.

At block 510, the antenna 100 can be modeled in free space, similar to above. The antenna 100 and the device 150 can be arranged to reflect the orientation of the exposure plane 160 to the aperture plane 140 (e.g., the XZ plane) as shown in FIG. 2, for example.

At block 520, the simulation can provide power densities in or across the exposure plane 160 for all test configurations. As used herein, a test configuration is a transmission state of the device 150 that can represent a fixed combination of amplitudes and phases of feed signals to different antenna array elements (of e.g., the antenna 100). In some embodiments, “all test configurations” can be all angles about the transmitting antenna 100. In some other embodiments, this can also refer to a select number of locations around the antenna for which testing is needed.

At block 530, the worst case antenna configurations are determined. As used herein, the “worst case” can be the test configuration of the antenna 100 that results in the highest mmWave exposure (e.g., SAR or power density) in the exposure plane 160 to, for example, a user operating the device 150. Note that the antenna array (e.g., the antenna 100) can have several test configurations where the amplitude and phase of feed signals to antenna elements can be varied in order to steer the main beam to establish a good communication link. In some embodiments, the top few worst configurations are evaluated.

The mmWave measurements on worst-case configurations in the near-field can be combined with back transformation of fields using the PWS method to obtain power density in exposure plane 160. Since the exposure plane 160 can lie in various positions relative to the device 150 (and the antenna 100), the simulations of, and measurements taken (e.g., at 2λ and 4λ planes) may not be parallel with the aperture plane 140. The validated near field measurement method (e.g., the method 400) can then be used to assess the worst case configurations.

At block 540 the device 150 containing the antenna 110 can be mounted in fixed position to provide stability for measuring the EM radiation 110. This can be similar to mounting the antenna 100 in the mock-up of the device 150 as described above in block 430.

At block 550, the EM radiation 110 can be measured in two polarizations. As used herein, the polarizations can refer to rotating the probe 115 is 90 degrees to capture both vertical and horizontal polarizations of energy fields/power density (e.g., of the EM radiation 110). Both polarizations can be used to obtain total field strength/power density. This can be done (using, for example, the probe 115) within planes separated from the antenna 100 and parallel to the exposure plane 160 (e.g., at 2λ and 4λ as shown by the inclined scan plane 125 and the inclined transform plane 304). The first and second planes, or the 4λ and 2λ planes can therefore be similar to the orientation of the inclined scan plane 125 and inclined transform plane 304, respectively. The measurements can capture the amplitude and phase of the EM radiation (e.g., EM field 110) along the planes at 2λ and 4λ parallel to the exposure plane 160 for the identified worst-case configurations. The measured EM-fields can then be back-transformed using the PWS technique to obtain the power density at the exposure plane 160. It should be appreciated that distances other than 2λ and/or 4λ can be used without departing from the disclosure.

At block 555, the measurements taken at block 550 can be validated using a variation of the method 400. As such, the measurements taken at the 4λ plane (similar to the inclined plane 125) can be back transformed to the 2λ plane (e.g., the inclined transform plane 304) and validated by comparing the back-transform values to the measurements taken at the 2λ plane (e.g., the inclined transform plane 304). If the values correlate to within a measurement uncertainty (e.g., tolerance) of the probe 115, then the method 500 can proceed to block 560. Thus, the simulation of block 510 can be used as a simulation setup for block 520. Accordingly block 510, block 520, and block 530, together illustrate the simulation to determine worst cases.

At block 560, the back transforms from 2λ and from 4λ to the exposure plane (e.g., from the inclined plane 125 to the exposure plane 160, and from the inclined transform plane 304 to the exposure plane 160 in FIG. 3) for a few (e.g., two to five) or a portion of the worst configurations can be calculated. It should be appreciated that distances other than 2λ and/or 4λ can be used without departing from the disclosure.

At block 570, the values of power density in the exposure plane 160 for the antenna 100 within the device 150 can then be compared to a given standard or regulatory limits. Accordingly, the method 500 can be used to determine compliance with a set of regulations, such as FCC regulations.

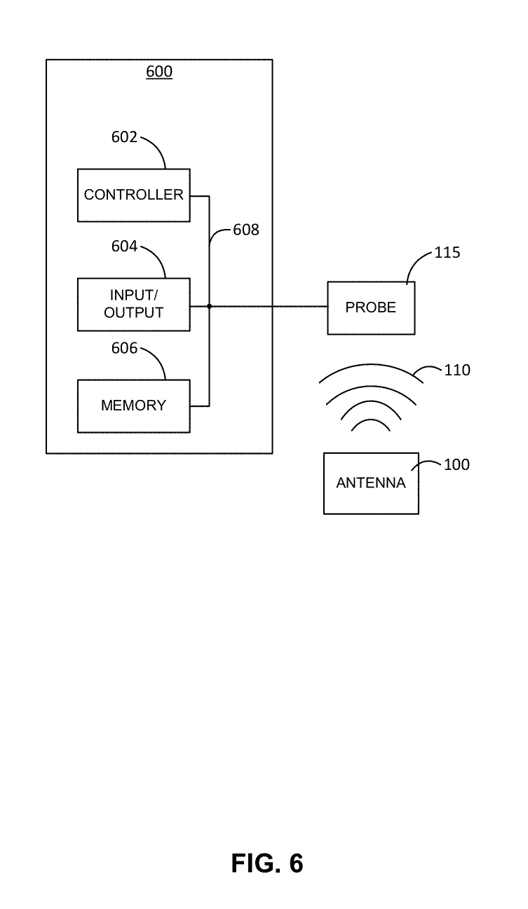

FIG. 6 is a functional block diagram of a device for implementing the methods disclosed herein. A device 600 can be used for measuring power density of the antenna 100 and validating various measurement methods, as described herein.

The device 600 can have a controller 602, an input/output (I/O) terminal (terminal) 604, one or more memories 606, and a communication link 608. In particular, the controller 602 can be a computer, one or more processors, or microprocessors, coupled to the one or more memories 606 and the terminal 604. The controller 602 can be operably coupled to the terminal 604 via the communication link 608. The terminal 604 can further have one or more user interfaces for user interaction and configuration.

The controller 602 can control operation of the device 600. For example, the terminal 604 can receive, for example, power density measurements from the probe 115 via the communication link 608. The controller 602 can save the power density measurements to the memory 606. The controller 602 (or e.g., one or more processors, a math co-processor within the controller 602) can calculate the back-transformed power density measurements for accurate modeling and validation of the various methods described herein (e.g., FIG. 3, FIG. 4, FIG. 5).

The controller 602 can be a computer having real time control capability. In particular, the controller 602 can include a multi-core processor, a memory, a communication device, a power supply, a user output (e.g., a display), and a user input (e.g., a keyboard). In some embodiments, the device 600 can be an industrial PC.

Those of skill will appreciate that the various illustrative blocks described in connection with the embodiments disclosed herein can be implemented in various forms. Some blocks have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the disclosure. In addition, the grouping of functions within a block or step is for ease of description. Specific functions or steps can be moved from one block or distributed across to blocks without departing from the present disclosure.

The various illustrative logical blocks described in connection with the embodiments disclosed herein, can be implemented or performed with a general purpose processor, a digital signal processor (DSP), application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

The steps of a method described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium. An exemplary storage medium can be coupled to the processor such that the processor can read information from, and write information to, the storage medium. In the alternative, the storage medium can be integral to the processor. The processor and the storage medium can reside in an ASIC.

The above description of the disclosed embodiments is provided to enable any person skilled in the art to make or use the present disclosure. Various modifications to these embodiments will be readily apparent to those skilled in the art, and the generic principles described herein can be applied to other embodiments without departing from the spirit or scope of the present disclosure. Thus, it is to be understood that the description and drawings presented herein represent a presently preferred embodiment of the present disclosure and are therefore representative of the subject matter which is broadly contemplated by the present disclosure. It is further understood that the scope of the present disclosure fully encompasses other embodiments that may become obvious to those skilled in the art and that the scope of the present disclosure is accordingly limited by nothing other than the appended claims.

1. A method for determining power density measurements of electromagnetic (EM) transmissions from an antenna of a wireless electronic device, the antenna having an aperture plane, the method comprising:
measuring, with a measuring device having a measurement error, a first power density distribution of the transmissions across a scan plane, the scan plane being parallel to and separated from the aperture plane and by a first distance;
determining, by a controller, a first back transformed power density distribution of the transmissions across a transform plane using the first power density distribution, the transform plane being parallel to and separated from the aperture plane by a second distance, the second distance being different than the first distance;
measuring, with the measuring device, a second power density distribution of the transmissions across an inclined scan plane, the inclined scan plane being non-parallel to aperture plane, the inclined scan plane and the scan plane intersecting at a first intersection;
determining, by the controller, a second back transformed power density distribution of the transmissions across an inclined transform plane using the second power density distribution, the inclined transform plane being parallel to the inclined scan plane and intersecting the transform plane at a second intersection; and
determining, by the controller, that the second back transformed power density distribution is within a measurement error of the first back transformed power density distribution at the second intersection.

2. The method of claim 1 further comprising determining that the first power density distribution is within a measurement error of the second power density distribution at the first intersection.

3. The method of claim 1 further comprising:
modeling, by the controller, a simulated power density distribution of the antenna in free space within a simulation error;
determining, by the controller, a power density at an exposure plane based on the simulated power density distribution;
determining, by the controller, a third back transformed power density distribution at the exposure plane, based on measurements of the power density distribution at a third distance from the antenna; and
determining, by the controller, that the simulated power density distribution at the exposure plane is within a combined simulation and measurement error of the third back transformed power density distribution.

4. The method of claim 1 wherein measuring the first power density distribution comprises measuring first power levels at a plurality of points separated by a regular interval across the scan plane in two dimensions and interpolating between the plurality of points.

5. The method of claim 1, wherein the first back transform and the second back transform are performed using the Plane Wave Spectrum (PWS) method.

6. A method for determining power density distribution of electromagnetic (EM) transmissions across an exposure plane of an antenna of a wireless electronic device, the method comprising:
determining, by a controller, one or more worst case configurations within an exposure plane based on a power density distribution of the antenna in free space;
measuring, with a measuring device having a measurement error, power density distribution in amplitude and phase in two polarizations across a first plane at a first distance from the exposure plane and across a second plane at a second distance from the exposure plane, the first plane and the second plane being parallel to the exposure plane;
first back transforming, by the controller, power density distribution of the first plane to the second plane for the one or more worst case configurations,
second back transforming, by the controller, power density distribution from the first plane to the exposure plane for the one or more worst case configurations, and
third back transforming, by the controller, power density distribution from the second plane to the exposure plane for the one or more worst case configurations.

7. The method of claim 6 further comprising comparing the back transformed power density distributions at the second distance to the measured power density distributions at the second distance.

8. The method of claim 6 further comprising comparing the power density distribution back transformed from the first distance to the exposure plane to the power density distribution back transformed from the second distance to the exposure plane.

9. The method of claim 6 further comprising, determining, by the controller, that the one or more worst case configurations in the exposure plane are within a predetermined limit based on a comparison of values determined by the second back transforming and the third back transforming.

10. The method of claim 6 further comprising modeling, by the controller, the antenna in free space to determine the one or more worst case configurations.

11. The method of claim 10 further comprising obtaining power density measurements across the exposure plane for all test configurations determined by the modeling.

12. The method of claim 6, wherein the first distance is four times a wavelength of the transmissions and the second distance is two times the wavelength of the transmissions.

13. The method of claim 6, wherein the first, second, and third back transforming are performed using a Plane Wave Spectrum (PWS) method.

14. A device for determining power density distribution of electromagnetic (EM) transmissions across an exposure plane of an antenna of a wireless electronic device, the device comprising:
a measuring device operable to measure power density distribution of the antenna in amplitude and phase in two polarizations across a first plane at a first distance from the exposure plane and across a second plane at a second distance from the exposure plane, the first plane and the second plane being parallel to the exposure plane; and
a controller operable to
determine one or more worst case configurations within the exposure plane of the antenna based on a power density distribution of the antenna in free space;
first back transforming power density distribution of the first plane to the second plane for the one or more worst case configurations,
second back transforming power density distribution from the first plane to the exposure plane for the one or more worst case configurations, and
third back transforming power density distribution from the second plane to the exposure plane for the one or more worst case configurations.

15. The device of claim 14, wherein the controller is further configured to compare the back transformed power density distributions at the second distance to the measured power density distributions at the second distance.

16. The device of claim 14, wherein the controller is further configured to compare the power density distribution back transformed from the first distance to the exposure plane to the power density distribution back transformed from the second distance to the exposure plane.

17. The device of claim 14, wherein the controller is further configured to determine that the one or more worst case configurations in the exposure plane are within a predetermined limit based on a comparison of values determined by the second back transforming, and the third back transforming.

18. The device of claim 14, wherein the controller is further configured to model the antenna in free space to determine the one or more worst case configurations.

19. The device of claim 14, wherein the exposure plane is nonparallel to an aperture plane of the antenna.

20. The device of claim 14, wherein the first, the second, and the third back transforming are performed using a Plane Wave Spectrum (PWS) method.

21. A non-transitory computer-readable medium for determining power density distribution of electromagnetic (EM) transmissions across an exposure plane of an antenna of a wireless electronic device, the medium comprising instructions that when executed by one or more processors cause a computer to:
determine one or more worst case configurations within an exposure plane based on a power density distribution of the antenna in free space;
measure power density distribution in amplitude and phase in two polarizations across a first plane at a first distance from the exposure plane and across a second plane at a second distance from the exposure plane, the first plane and the second plane being parallel to the exposure plane;
back transform power density distribution of the first plane to the second plane for the one or more worst case configurations,
back transform power density distribution from the first plane to the exposure plane for the one or more worst case configurations, and
back transform power density distribution from the second plane to the exposure plane for the one or more worst case configurations.

22. The computer-readable medium of claim 21 further comprising instructions that cause the computer to compare the back transformed power density distributions at the second distance to the measured power density distributions at the second distance.

23. The computer-readable medium of claim 20 further comprising instructions that cause the computer to compare the power density distribution back transformed from the first distance to the exposure plane to the power density distribution back transformed from the second distance to the exposure plane.

24. The computer-readable medium of claim 21 further comprising instructions that cause the computer to determine that the one or more worst case configurations in the exposure plane are within a predetermined limit based on a comparison of values determined by the second back transforming, and the third back transforming.

25. The computer-readable medium of claim 21 further comprising instructions that cause the computer to model the antenna in free space to determine the one or more worst case configurations.

26. The computer-readable medium of claim 21, wherein the exposure plane is nonparallel to an aperture plane of the antenna.

27. The computer-readable medium of claim 21, wherein the first, second, and third back transforming are performed using a Plane Wave Spectrum (PWS) method.
